(19) United States
(12) Patent Application Publication
(10) Pub. No.: US 2024/0421249 A1
(43) Pub. Date: Dec. 19, 2024

(54) LIGHT-EMITTING DEVICE

(71) Applicant: EPISTAR CORPORATION, Hsinchu (TW)

(72) Inventors: Meng-Hsiang HONG, Hsinchu (TW); Yu-Ling LIN, Hsinchu (TW); Chao-Hsing CHEN, Hsinchu (TW); Chen OU, Hsinchu (TW); Chien-Ya HUNG, Hsinchu (TW)

(21) Appl. No.: 18/740,925

(22) Filed: Jun. 12, 2024

(30) Foreign Application Priority Data
Jun. 15, 2023 (TW) 112122399

(51) Int. Cl. H01L 33/10; H01L 33/38; H01L 33/62

(52) U.S. Cl. CPC H01L 33/10; H01L 33/387; H01L 33/62

(57) ABSTRACT

A light-emitting device comprises a first semiconductor layer; a semiconductor mesa, comprising an active layer and a second semiconductor layer and comprising an inclined surface; a contact electrode covering the second semiconductor layer and comprising a first side surface; an insulating reflective structure covering the contact electrode and comprising a plurality of insulating reflective structure openings; a connection layer covering the insulating reflective structure and filling into the plurality of insulating reflective structure openings, and comprising a second side surface; and a metal reflective layer covering the connection layer and filling into the plurality of insulating reflective structure openings, and comprising a third side surface; wherein in a cross-sectional view of the light-emitting device, a first pitch is between the first side surface and the inclined surface, a third pitch is between the third side surface and the inclined surface, and the third pitch is smaller than the first pitch.

### REFERENCE TO RELATED APPLICATION

This application claims the right of priority based on Taiwan Application Serial No. 112122399, filed on Jun. 15, 2023, and the content of which is hereby incorporated by reference in its entirety.

### TECHNICAL FIELD

The application relates to a light-emitting device, more specifically, to a flip-chip light-emitting device comprising a metal reflective layer and an insulating reflective layer.

### DESCRIPTION OF BACKGROUND ART

Light-emitting diode (LED) is a solid-state semiconductor light-emitting device, which has the advantages of low power consumption, low heat generation, long lifetime, shockproof, small size, high response speed and good optical-electrical characteristics, such as stable emission wavelength. Therefore, light-emitting diodes have been widely applied in household appliances, equipment indicator lights, and optoelectronic products, and so forth.

### SUMMARY OF THE APPLICATION

In accordance with an embodiment of the present application, a light-emitting device comprises a first semiconductor layer; a semiconductor mesa, comprising an active layer and a second semiconductor layer and comprising an inclined surface connected to the first semiconductor layer; a contact electrode covering the second semiconductor layer and comprising a first side surface; an insulating reflective structure covering the contact electrode and comprising a plurality of insulating reflective structure openings to expose the contact electrode; a connection layer covering the insulating reflective structure and filling into the plurality of insulating reflective structure openings, and comprising a second side surface; and a metal reflective layer covering the connection layer and filling into the plurality of insulating reflective structure openings of the insulating reflective structure, and comprising a third side surface; wherein in a cross-sectional view of the light-emitting device, a first pitch is between the first side surface and the inclined surface, a third pitch is between the third side surface and the inclined surface, and the third pitch is smaller than the first pitch.

### BRIEF DESCRIPTION OF THE DRAWINGS

The above and other aspects of the application will become better understood with regard to the following detailed description of the preferred but non-limiting embodiment(s). The following description is made with reference to the accompanying drawings. It is noted that, in accordance with the standard practice in the industry, various features are not drawn to scale. In fact, the dimensions of the various features may be arbitrarily increased or reduced for clarity of discussion.

FIG. 1 shows a top view of a light-emitting device 1 according to an embodiment of the present application.

FIG. 2 shows a cross-sectional view of the light-emitting device 1 along line L-L′ of FIG. 1.

FIG. 3A shows a top view of a plurality of insulating reflective structure openings of region A defined by the dash line of FIG. 1 according to an embodiment of the present application.

FIG. 3B shows a top view of a plurality of insulating reflective structure openings of region A defined by the dash line of FIG. 1 according to another embodiment of the present application.

FIG. 3C shows a top view of a plurality of insulating reflective structure openings of region B defined by the dash line of FIG. 1 according to an embodiment of the present application.

FIG. 3D shows a top view of a plurality of insulating reflective structure openings of region B defined by the dash line of FIG. 1 according to another embodiment of the present application.

FIG. 4 shows an EOS testing diagram of the light-emitting device according to an embodiment of the present application.

FIG. 5A shows a cross-sectional view along line O-O′ of FIG. 3A or along line P-P′ of FIG. 3B according to an embodiment of the present application.

FIG. 5B shows a cross-sectional view along line O-O′ of FIG. 3A or along line P-P′ of FIG. 3B according to another embodiment of the present application.

FIG. 6 shows a table of a first pitch between a first side surface of a contact electrode and an inclined surface of a semiconductor mesa versus the optoelectronic characteristics of the light-emitting devices.

FIG. 7 shows an enlarged view of region C defined by the dash line of FIG. 1.

FIG. 8 shows a cross-sectional view along line I-I′ of FIG. 7 according to an embodiment of the present application.

FIG. 9 shows a cross-sectional view along line I-I′ of FIG. 7 according to another embodiment of the present application.

FIG. 10 shows a cross-sectional view along line I-I′ of FIG. 7 according to another embodiment of the present application.

FIG. 11 shows a cross-sectional view along line I-I′ of FIG. 7 according to another embodiment of the present application.

FIGS. 12A-12D show cross-sectional views of manufacturing the insulating reflective structure opening of the light-emitting device 1 according to an embodiment of the present application.

FIG. 13 shows a schematic view of a light-emitting apparatus 2 according to an embodiment of the present application.

FIG. 14 shows a schematic view of a light-emitting apparatus 3 according to an embodiment of the present application.

FIG. 15 shows a schematic view of a backlight module 4 according to an embodiment of the present application.

FIG. 16 shows a schematic view of a display 5 according to an embodiment of the present application.

FIG. 17 shows a schematic view of a light-emitting apparatus 6 according to an embodiment of the present application.

FIG. 18 shows a schematic view of a light-emitting apparatus 7 according to an embodiment of the present application.

### DETAILED DESCRIPTION OF THE APPLICATION

The following disclosure provides many different embodiments for implementing different features of the present application. The following disclosure describes specific examples of each element and its arrangement to simplify the explanation. These specific examples are not intended to be limited. For example, if the embodiment of the present disclosure describes that a first feature is formed on or above a second feature, it means that the first feature and the second feature are in direct contact, or additional features are formed between the first feature and the second feature such that the first feature and the second feature may not be in direct contact.

It should be understood that other operating steps may be performed before, between or after the method, and in other embodiments of the method, part of the operating steps may be replaced or omitted.

In addition, space-related words may be used, such as “under”, “below”, “lower”, “above”, “on”, “higher” and the related, these spatially related terms are used to facilitate the description of the relationship between one element or feature(s) and another element or feature(s) in the illustrations. These spatially related terms include the various orientations of the device in use or operation, and the orientation depicted in the drawings. When the device is rotated to different orientations (rotated 45 degrees or at any other orientation), the spatially relative adjectives used in the device will be interpreted in accordance with the rotated orientation. Furthermore, when it is said that a first material layer is located on or above a second material layer, it includes the situation where the first material layer and the second material layer are in direct contact, or there may be one or more other materials disposed between them. In the case, there may not be direct contact between the first material layer and the second material layer. In some embodiments of the present disclosure, unless otherwise defined, terms related to joining and connecting, such as “connection” or “interconnection”, may mean that two structures are in direct contact, or may also mean that two structures are not in direct contact and there are other structures located between these two structures. And the terms about joining and connecting can also include the situation where both structures are movable or both structures are fixed.

In the specification, the terms “about”, “nearly”, “roughly”, “approximately”, “substantially”, “same”, and “similar” usually indicate within +15% of a characteristic value of a given value, or within +10%, or within +5%, or within +3%, or within +2%, or within +1%, or within the range of +0.5%. The quantities given here are approximate quantities, that is, in the absence of specific instructions for “about”, “nearly”, “roughly”, “approximately”, and “substantially”, they may still imply the meaning of “about”, “nearly”, “roughly”, “approximately”, and “substantially”.

It should be understood that, although the terms “first”, “second”, “third”, etc. are used herein to describe various elements, parts, regions, layers and/or sections, these elements, parts, regions, layers and/or sections should not be limited by these terms. These terms may only be used to distinguish one element, part, region, layer or section from another element, part, region, layer or section. Thus, a first element, part, region, layer or section discussed below could be termed as a second element, part, region, layer or section without departing from the teachings of the present disclosure.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and this disclosure. It should not be interpreted in an idealized or overly formal manner unless specifically defined in the embodiments of this present disclosure.

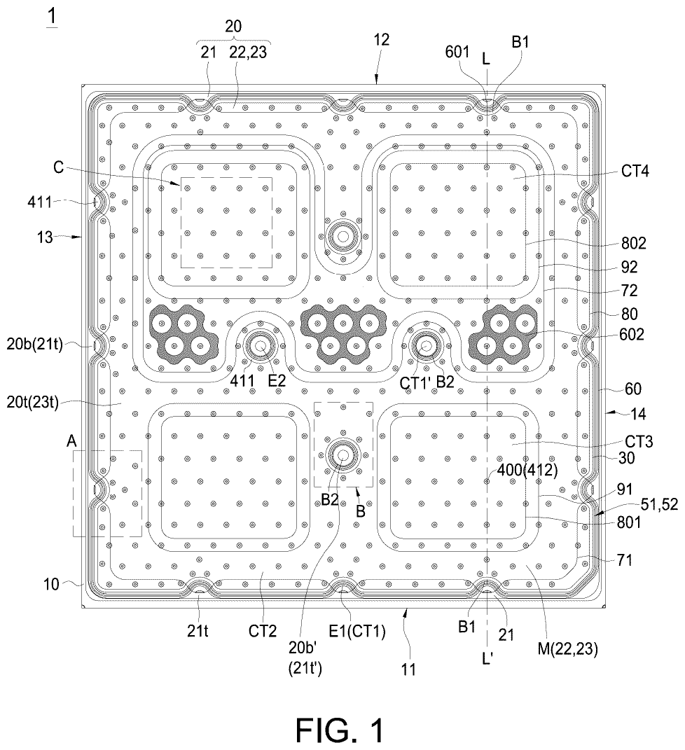

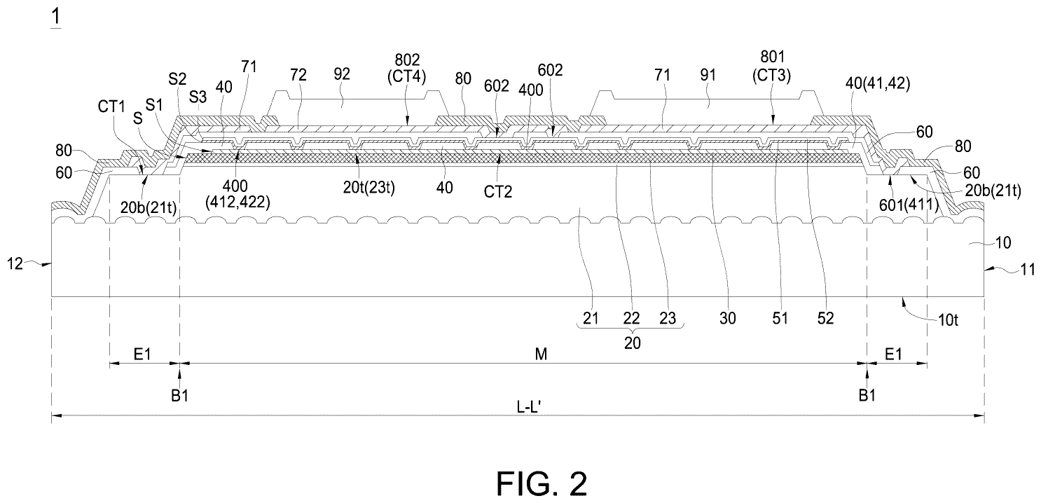

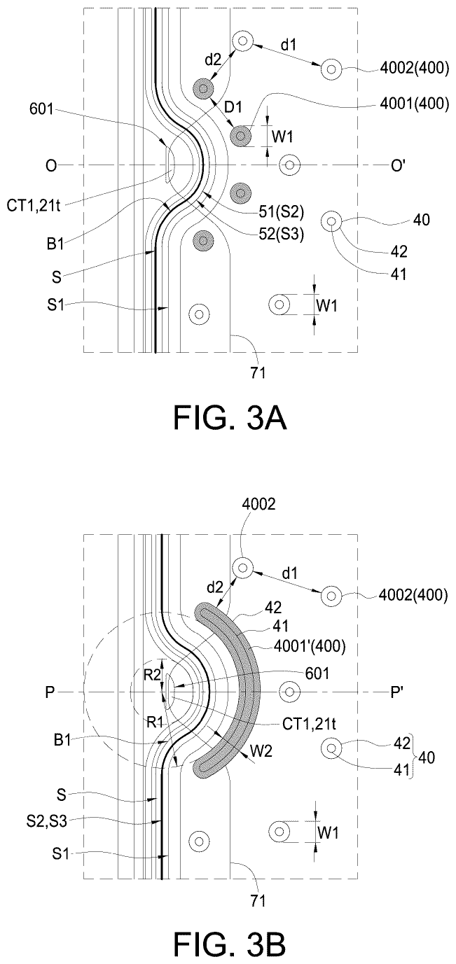

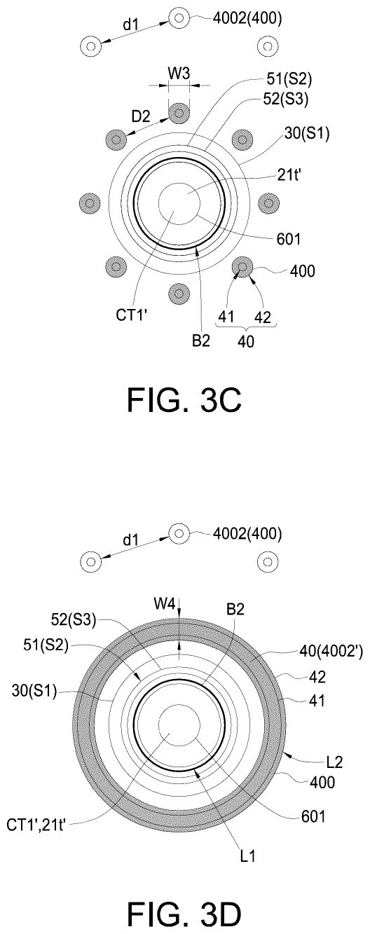

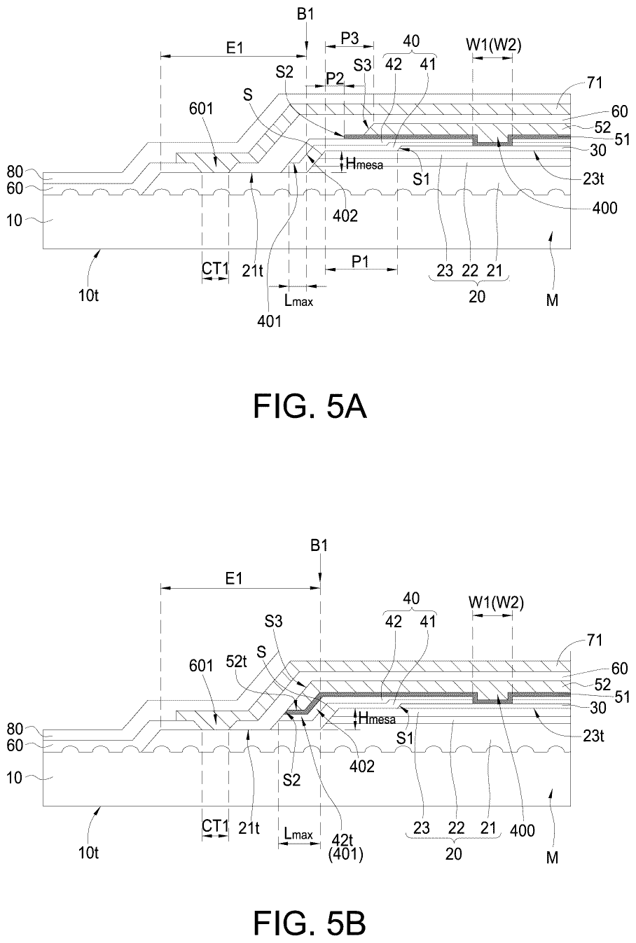

FIG. 1 shows a top view of a light-emitting device 1 according to an embodiment of the present application. FIG. 2 shows a cross-sectional view of the light-emitting device 1 along line L-L′ in FIG. 1. FIG. 3A shows a top view of a plurality of insulating reflective structure openings of region A defined by the dash line of FIG. 1. FIG. 5A shows a cross-sectional view along line O-O′ in FIG. 3A according to an embodiment of the present application.

As shown in FIGS. 1, 2, 3A and 5A, a light-emitting device 1 according to an embodiment comprises a substrate 10, a first semiconductor layer 21 located on the substrate 10, and a semiconductor mesa M located on the first semiconductor layer 21. The semiconductor mesa M comprises an active layer 22 and a second semiconductor layer 23, and comprises an inclined surface S connected to the first semiconductor layer 21. A contact electrode 30 is located on the second semiconductor layer 23 and comprises a first side surface S1. An insulating reflective structure 40 is located on the contact electrode 30 and comprises one or a plurality of insulating reflective structure openings 400 to expose the contact electrode 30. A connection layer 51 covers the insulating reflective structure 40 and fills into one or the plurality of insulating reflective structure openings 400, and comprises a second side surface S2 which is connected to the insulating reflective structure 40. A metal reflective layer 52 is located on the connection layer 51 and fills into one or the plurality of insulating reflective structure openings 400, and comprises a third side surface S3, wherein in a cross-sectional view of the light-emitting device 1, a first pitch P1 is between the first side surface S1 and the inclined surface S of the semiconductor mesa M, a second pitch P2 is between the second side surface S2 and the inclined surface S of the semiconductor mesa M, a third pitch P3 is between the third side surface S3 and the inclined surface S of the semiconductor mesa M, and the third pitch P3 is smaller than the first pitch P1. In one embodiment of the present application, the third side surface S3 of the metal reflective layer 52 can be connected to the connection layer 51 or the insulating reflective structure 40.

When the third side surface S3 is connected to the connection layer 51, the third side surface S3 and the second side surface S2 can be located on the same inclined plane (that is, the third side surface S3 and the second side surface S2 may have the same slope), or the second pitch P2 is smaller than the third pitch P3. When the third side surface S3 is connected to the insulating reflective structure 40, the third pitch P3 is smaller than the second pitch P2, and the metal reflective layer 52 covers the second side surface S2 of the connection layer 51.

The light-emitting device 1 comprises a second insulating layer 60 covering the metal reflective layer 52 and the insulating reflective structure 40. The second insulating layer 60 comprises a first opening 601 of the second insulating layer 60 located on the first semiconductor layer 21 and a second opening 602 of the second insulating layer 60 located on the metal reflective layer 52. A first extension electrode 71 covers the semiconductor mesa M and covers the first opening 601 of the second insulating layer 60. A second extension electrode 72 covers the semiconductor mesa M and covers the second opening 602 of the second insulating layer 60. A protection layer 80 covers the first extension electrode 71 and the second extension electrode 72, and comprises a first opening 801 of the protection layer 80 located on the first extension electrode 71 and a second opening 802 of the protection layer 80 located on the second extension electrode 72. A first electrode pad 91 covers the first opening 801 of the protection layer 80 and is electrically connected to the first semiconductor layer 21 through the first extension electrode 71. A second electrode pad 92 covers the second opening 802 of the protection layer 80 and is electrically connected to the second semiconductor layer 23 through the second extension electrode 72.

The substrate 10 can be a growth substrate for the epitaxial growth of a semiconductor structure 20. In one embodiment, the semiconductor structure 20 comprises a first semiconductor layer 21, an active layer 22, and a second semiconductor layer 23. The substrate 10 comprises gallium arsenide (GaAs) wafer for epitaxially growing aluminum gallium indium phosphide (AlGaInP), or sapphire (Al₂O₃) wafer, gallium nitride (GaN) wafer, silicon carbide (SiC) wafer, or aluminum nitride (AlN) wafer for epitaxially growing gallium nitride (GaN), indium gallium nitride (InGaN), or aluminum gallium nitride (AlGaN).

In one embodiment of the present application, the light-emitting device 1 may not comprise a substrate 10. For example, the substrate 10 may be a growth substrate for growing the semiconductor structure 20. Then, the substrate 10 can be separated from the semiconductor structure 20 by laser lift off or chemical lift-off.

In one embodiment of the present application, the semiconductor structure 20 with optoelectronic characteristics, such as light-emitting stack, can be formed on the substrate 10 by metal-organic chemical vapor deposition (MOCVD), molecular beam epitaxy (MBE), hydride vapor phase epitaxy (HVPE), physical vapor deposition (PVD), or ion plating. Physical vapor deposition comprises sputtering or evaporation.

The wavelength of the light emitted from the light-emitting device 1 is adjusted by changing the physical and chemical composition of one or more layers in the semiconductor structure 20. The semiconductor structure 20 comprises a first semiconductor layer 21, an active layer 22, and a second semiconductor layer 23. The material of the semiconductor structure 20 comprises a group III-V semiconductor material, such as AlₓIn_{y}Ga_{(1-x-y)}N or AlₓIn_{y}Ga_{(1-x-y)}P, wherein 0≤x, y≤1; (x+y)≤1. According to the material of the active layer 22, when the material of the semiconductor structure 20 is AlInGaP material, red light having a wavelength between 610 nm and 650 nm or yellow light having a wavelength between 550 nm and 570 nm can be emitted. When the material of the semiconductor structure 20 comprises InGaN material, blue light having a wavelength between 400 nm and 490 nm or green light having a wavelength between 530 nm and 570 nm can be emitted. When the material of the semiconductor structure 20 comprises AlGaN or AlInGaN material, UV light having a wavelength between 250 nm and 400 nm can be emitted.

The first semiconductor layer 21 and the second semiconductor layer 23 both can be a cladding layer or a confinement layer and have different conductivity types, electrical properties, polarities, or doping elements for providing electrons or holes. For example, the first semiconductor layer 21 is an n-type semiconductor, and the second semiconductor layer 23 is a p-type semiconductor. The active layer 22 is formed between the first semiconductor layer 21 and the second semiconductor layer 23. The electrons and holes combine in the active layer 22 under a current driving to convert electric energy into light energy to emit a light. The active layer 22 can be a single heterostructure (SH), a double heterostructure (DH), a double-side double heterostructure (DDH), or a multi-quantum well structure, MQW). The material of the active layer 22 can be i-type, p-type, or n-type semiconductor. The first semiconductor layer 21, the active layer 22, or the second semiconductor layer 23 may be a single layer or a structure comprising a plurality of sub-layers.

In one embodiment, the semiconductor structure 20 can further comprise a buffer layer (not shown) located between the first semiconductor layer 21 and the substrate 10 to release the stress caused by lattice mismatch between the materials, the lattice dislocation and the lattice defect can thus be reduced and the epitaxial quality can be improved. The buffer layer can be a single layer or a structure comprising a plurality of sub-layers. In one embodiment, an aluminum nitride (AlN) layer formed by PVD method can be the buffer layer located between the semiconductor structure 20 and the substrate 10 to improve the epitaxial quality of the semiconductor structure 20. In one embodiment, a target is composed of aluminum nitride when the aluminum nitride (AlN) layer is formed by PVD method. In another embodiment, a target composed of aluminum can be used, and aluminum nitride can be formed by reacting the aluminum target with a nitrogen source.

As shown in FIGS. 1 and 2, the semiconductor structure 20 comprises a first recessed region E1, a second recessed region E2, and a semiconductor mesa M surrounded by the first recessed region E1. In one embodiment, the first recessed region E1 and the second recessed region E2 can be formed by etching to remove the second semiconductor layer 23, the active layer 22 and a portion of the first semiconductor layer 21. In FIGS. 1 and 2, the symbol “B1” represents a first boundary B1 between the first recessed region E1 and the semiconductor mesa M. In FIG. 1, the symbol “B2” represents a second boundary B2 between the second recessed region E2 and the semiconductor mesa M. An upper surface 20t of the semiconductor mesa M (an upper surface 23t of the second semiconductor layer 23) may be higher than an upper surface 20b of the first recessed region E1 (an upper surface 21t of the first semiconductor layer 21) and an upper surface 20b′ of the second recessed region E2 (an upper surface 21t′ of the first semiconductor layer 21). In one embodiment, the semiconductor mesa M may become narrower toward its top. Therefore, the side surface of the semiconductor mesa M can be an inclined surface S.

As shown in FIG. 1, in one embodiment, a part of the upper surface 20b of the first recessed region E1 can be a first contact region CT1, and a part of the upper surface 20b′ of the second recessed region E2 can be a first contact subregion CT1′. In one embodiment, a part of the upper surface 20t of the semiconductor mesa M is defined as a second contact region CT2. In one embodiment, a ratio (A1/A2) of a first total area A1 of the plurality of first contact subregions CT1′ to a second total area A2 of the plurality of first contact regions CT1 is in a range between 1 and 2 to improve the current distribution of the light-emitting device 1. If the ratio (A1/A2) is less than 1, the brightness of the light-emitting device 1 is decreased. If the ratio (A1/A2) is greater than 2, the voltage (Vf) of the light-emitting device 1 is increased.

As shown in FIG. 1, the substrate 10 comprises a first side 11, a second side 12, a third side 13 and a fourth side 14. The semiconductor mesa M can be spaced apart from the first side 11, the second side 12, the third side 13, and the fourth side 14, and the first recessed region E1 can be disposed between the semiconductor mesa M and any side of the first side 11, the second side 12, the third side 13, and the fourth side 14. For example, the first recessed region E1 can be disposed between the semiconductor mesa M and the first side 11 and between the semiconductor mesa M and the second side 12, or between the semiconductor mesa M and the third side 13 and between the semiconductor mesa M and the fourth side 14. The first side 11 and the second side 12 can be opposite to each other, and the third side 13 and the fourth side 14 can be opposite to each other. In one embodiment, a plurality of second recessed regions E2 spaced apart from each other having a long stripped, rectangular, circular or elliptical shape can be disposed inside the semiconductor mesa M.

The contact electrode 30 can be directly disposed on the second semiconductor layer 23. The region where the contact electrode 30 contacts the second semiconductor layer 23 constitutes the second contact region CT2, and the contact electrode 30 is electrically connected to the second semiconductor layer 23. The contact electrode 30 can spread the current injected from the outside and then inject it into the second semiconductor layer 23 via the upper surface 20t of the semiconductor mesa M (the upper surface 23t of the second semiconductor layer 23).

As shown in FIG. 1, in a top view of the light-emitting device 1, the insulating reflective structure opening 400 comprises a circle, a semicircle, an ellipse, a triangle, a rectangle, a polygon, an arc, or an annular shape. In one embodiment, the insulating reflective structure 40 comprises a plurality of insulating reflective structure openings 400 disposed on the semiconductor mesa M. The plurality of insulating reflective structure openings 400 may be arranged on the semiconductor mesa M in a hexagonal closest-packed grid pattern, but is not limited thereto. In another embodiment, the plurality of insulating reflective structure openings 400 may be arranged in various patterns, such as a rectangular plaid pattern. As shown in FIG. 2, the insulating reflective structure 40 covers the inclined surface S of the semiconductor mesa M, and covers a part of the first semiconductor layer 21 and a part of the second semiconductor layer 23. For example, the insulating reflective structure 40 may cover a part of the upper surface 21t of the first semiconductor layer 21 and a part of the upper surface 23t of the second semiconductor layer 23.

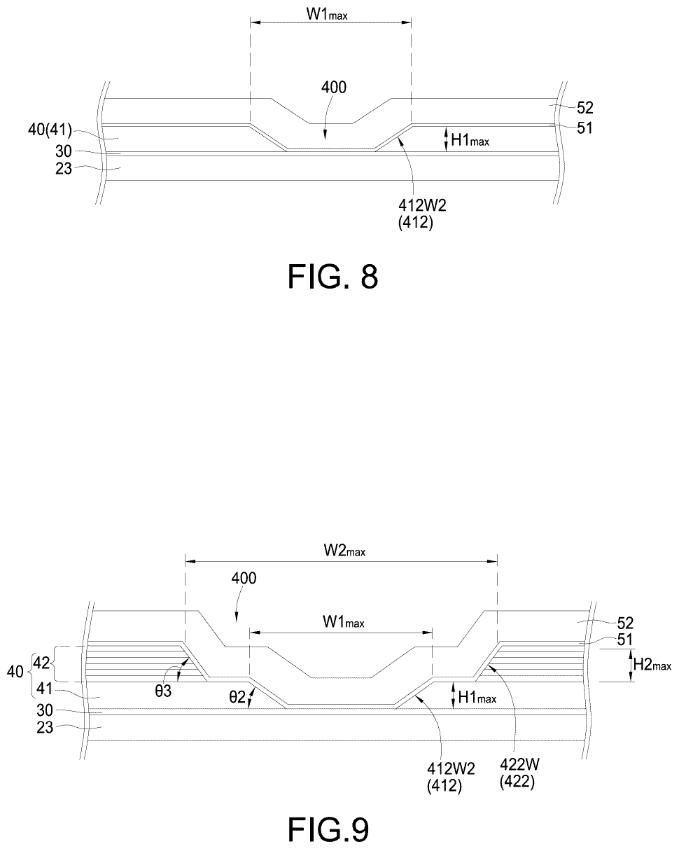

FIG. 7 is an enlarged view of the region C defined by the dash line of FIG. 1. FIG. 8 is a cross-sectional view along line I-I′ of FIG. 7 according to an embodiment of the present application. FIGS. 9, 10 and 11 are cross-sectional views along line I-I′ of FIG. 7 according to another embodiment of the present application. In one embodiment, the insulating reflective structure 40 comprises a first insulating layer 41 or an insulating reflective layer 42. In another embodiment, the insulating reflective structure 40 comprises a first insulating layer 41 and an insulating reflective layer 42.

In one embodiment, as shown in FIGS. 1, 2, 7 and 8, when the insulating reflective structure 40 comprises the first insulating layer 41, the first insulating layer 41 is located on the contact electrode 30 and covers the inclined surface S of the semiconductor mesa M. The first insulating layer 41 comprises a plurality of first insulating layer first openings 411 to expose the first contact region CT1 and the first contact subregion CT1′ of the first semiconductor layer 21. In this embodiment, the plurality of insulating reflective structure openings 400 comprises a plurality of first insulating layer second openings 412 to expose the contact electrode 30. In one embodiment, the first insulating layer 41 is taken as an insulating film and can be a single-layer structure comprising oxide or nitride, for example, silicon oxide, silicon nitride, metal oxide or metal nitride while the metal can be selected from titanium (Ti), zirconium (Zr), niobium (Nb), tantalum (Ta), or aluminum (Al). In another embodiment, the first insulating layer 41 may also be a multi-layer structure, for example, a stack composed of any two or more of the above-mentioned oxides or nitrides, such as a multi-layer structure composed of SiO₂, TiO₂ and Al₂O₃.

In one embodiment, referring to FIGS. 1, 2, 7, 9, 10 and 11, when the insulating reflective structure 40 comprises a first insulating layer 41 and an insulating reflective layer 42, the insulating reflective layer 42 can be composed of a material with a refractive index lower than that of the second semiconductor layer 23. The material of the insulating reflective layer 42 comprises SiO₂, SiN, SiOₓN_{y}, TiO₂, Si₃N₄, Al₂O₃, TIN, AlN, ZrO₂, TiAlN, TiSiN, HfO, TaO₂, Nb₂O₅, or MgF₂. In one embodiment, the insulating reflective layer 42 has a multi-layer film structure in which insulating sub-layers with different refractive indexes are alternately stacked, such as a distributed Bragg reflector (DBR). The multi-layer film structure may be a structure comprising pairs of first insulating sub-layers each having a first refractive index and second insulating sub-layers each having a second refractive index alternately stacked, wherein the materials of the first insulating sub-layers and the second insulating sub-layers are selected from the above materials, but are not limited thereto. For example, SiO₂/TiO₂ or SiO₂/Nb₂O₅ can be alternately stacked.

The bottommost layer or the topmost layer of the insulating reflective layer 42 can use one silicon oxide, silicon nitride, metal oxide or metal nitride while the metal can be selected from titanium (Ti), zirconium (Zr), niobium (Nb), tantalum (Ta), or aluminum (Al). In one embodiment, the bottommost layer and the topmost layer of the insulating reflective layer 42 comprise different materials and/or different thicknesses and/or different formation processes from that of the intermediate layer.

In one embodiment, when the insulating reflective structure 40 comprises a first insulating layer 41 and an insulating reflective layer 42, the first insulating layer 41 can comprise the same material as a part of material of the insulating reflective layer 42. For example, when the insulating reflective layer 42 is made of DBR comprising SiO₂, the first insulating layer 41 may be made of SiO₂. Although the first insulating layer 41 is made of the same material as a part of the insulating reflective layer 42, it is not required to have such a high film quality as the insulating film of DBR. Therefore, the first insulating layer 41 and the insulating reflective layer 42 can be made by different processes, respectively. The interface between the first insulating layer 41 and the insulating reflective layer 42 can be differentiated visually (e.g. SEM photos or TEM photos).

FIG. 3A is a top view of a plurality of insulating reflective structure openings 400 of region A defined by the dash line of FIG. 1. As shown in FIG. 3A, each of the plurality of insulating reflective structure openings 400 comprises a first width W1. Adjacent to or closest to the first boundary B1 of the first contact region CT1, the plurality of insulating reflective structure openings 400 comprises a first group of insulating reflective structure openings 4001 surrounding the first contact region CT1. In one embodiment, the first group of insulating reflective structure openings 4001 of the plurality of insulating reflective structure openings 400 is arranged along the first boundary B1 of the first contact region CT1. In one embodiment, the first group of insulating reflective structure openings 4001 of the plurality of insulating reflective structure openings 400 is arranged in an arc evenly spaced from each other by a first shortest distance D1, and a ratio of the first shortest distance D1 to the first width W1 (D1/W1) is between 1 and 3 or between 0.8 and 1.8. The plurality of insulating reflective structure openings 400 away from the first boundary B1 of the first contact region CT1 comprises a second group of insulating reflective structure openings 4002, which are evenly spaced from each other by a first shortest pitch d1, wherein the first shortest pitch d1 is greater than the first shortest distance D1. There is a second shortest pitch d2 between one of the first group of insulating reflective structure openings 4001 and one of the second group of insulating reflective structure openings 4002, wherein the second shortest pitch d2 can be the same as the first shortest pitch d1, the second shortest pitch d2 can be greater than the first shortest pitch d1, or the second shortest pitch d2 can be less than the first shortest pitch d1, thereby improving the current distribution at the first boundary B1. In one embodiment, in order to improve the current distribution of the region adjacent to the first contact region CT1, the first group of insulating reflective structure openings 4001 surrounding the first contact region CT1 comprises a total area larger than the exposed area of the first semiconductor layer 21 at the first opening 601 of the second insulating layer 60.

FIG. 3B is a top view of a plurality of insulating reflective structure openings 400 of region A defined by the dash line of FIG. 1 according to another embodiment of the present application. As shown in FIG. 3B, each of the plurality of insulating reflective structure openings 400 comprises a first width W1. The first group of insulating reflective structure openings 4001 adjacent to or closest to the first boundary B1 of the first contact region CT1 to surround the first contact region CT1 as shown in FIG. 3A can be altered to a single insulating reflective structure opening 4001′ as shown in FIG. 3B, and this single insulating reflective structure opening 4001′ conforms the contour of the first boundary B1 and thus has a shape, such as an arc shape having a second width W2 and a first radius of curvature R1. In this embodiment, the contour of the first boundary B1 comprises an arc shape having a second radius of curvature R2, and the first radius of curvature R1 is greater than the second radius of curvature R2. The second width W2 of the single insulating reflective structure opening 4001′ as shown in FIG. 3B can be the same as or different from the first width W1 of the plurality of insulating reflective structure openings 400 away from the first boundary B1. In one embodiment, the second width W2 of the single insulating reflective structure opening 4001′ may be greater or smaller than the first width W1 of the plurality of insulating reflective structure openings 400 away from the first boundary B1. The plurality of insulating reflective structure openings 400 away from the first boundary B1 of the first contact region CT1 comprises a second group of insulating reflective structure openings 4002, which are evenly spaced from each other by a first shortest pitch d1. There is a second shortest pitch d2 between the single insulating reflective structure opening 4001′ and one of the second group of insulating reflective structure openings 4002, wherein the second shortest pitch d2 can be the same as the first shortest pitch d1, the second shortest pitch d2 can be greater than the first shortest pitch d1, or the second shortest pitch d2 can be less than the first shortest pitch d1, thereby improving the current distribution at the first boundary B1. In one embodiment, in order to improve the current distribution of the region adjacent to the first contact region CT1, the single insulating reflective structure opening 4001′ surrounding the first contact region CT1 comprises a total area larger than the exposed area of the first semiconductor layer 21 at the first opening 601 of the second insulating layer 60.

FIG. 3C is a top view of a plurality of insulating reflective structure openings 400 of region B defined by the dash line of FIG. 1. In one embodiment, as shown in FIG. 3C, the plurality of insulating reflective structure openings 400 adjacent to or closest to the second boundary B2 of the first contact subregion CT1′ is arranged in a circle, evenly spaced from each other by a second shortest distance D2 to surround the first contact subregion CT1′, and a ratio of the second shortest distance D2 to a third width W3 of each of the plurality of insulating reflective structure openings 400 (D2/W3) is between 1 and 3 or between 0.8 and 1.8. Referring to FIGS. 3A and 3C, in one embodiment, the second shortest distance D2 between two adjacent insulating reflective structure openings 400 adjacent to the first contact subregion CT1′ as shown in FIG. 3C can be the same, greater than or smaller than the first shortest distance D1 that the first group of insulating reflective structure openings 4001 adjacent to the first contact region CT1 as shown in FIG. 3A comprises. The third width W3 of each of the plurality of insulating reflective structure openings 400 adjacent to the second boundary B2 of the first contact subregion CT1′ as shown in FIG. 3C can be the same or different from the first width W1 that each of the plurality of insulating reflective structure openings 400 adjacent to or closest to the first boundary B1 of the first contact region CT1 as shown in FIG. 3A comprises, or the same as or different from the second width W2 that the single insulating reflective structure opening 4001′ as shown in FIG. 3B comprises. In one embodiment, in order to improve the current distribution of the region adjacent to the first contact subregion CT1′, the plurality of insulating reflective structure openings 400 arranged in a circle surrounding the first contact subregion CT1′ comprises a total area larger than the exposed area of the first semiconductor layer 21 at the first opening 601 of the second insulating layer 60.

FIG. 3D is a top view of a plurality of insulating reflective structure openings 400 of region B defined by the dash line of FIG. 1 according to another embodiment of the present application. In this embodiment, the plurality of insulating reflective structure openings 400 surrounding the first contact subregion CT1′ as shown in FIG. 3C can be altered to a ring shape insulating reflective structure opening 4002′ as shown in FIG. 3D. As shown in FIG. 3D, the plurality of insulating reflective structure openings 400 adjacent to or closest to the second boundary B2 of the first contact subregion CT1′ comprises a ring shape insulating reflective structure opening 4002′ continuously surrounding the first contact subregion CT1′. The ring shape insulating reflective structure opening 4002′ comprises a fourth width W4 and a second perimeter L2, and the second perimeter L2 is greater than a first perimeter L1 of the first contact subregion CT1′. The fourth width W4 of the ring shape insulating reflective structure opening 4002′ as shown in FIG. 3D can be the same or different from the first width W1 that the first group of insulating reflective structure openings 4001 adjacent to or closest to the first boundary B1 of the first contact region CT1 as shown in FIG. 3A comprises, or the same as or different from the second width W2 that the single insulating reflective structure opening 4001′ as shown in FIG. 3B comprises. In one embodiment, in order to improve the current distribution of the region adjacent to the first contact subregion CT1′, the ring shape insulating reflective structure opening 4002′ surrounding the first contact subregion CT1′ comprises a total area larger than the exposed area of the first semiconductor layer 21 at the first opening 601 of the second insulating layer 60.

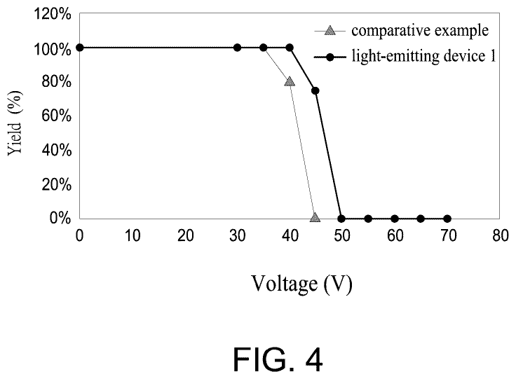

In one embodiment of the present application, as shown in FIGS. 3A and 3C, the first group of insulating reflective structure openings 4001 adjacent to the first boundary B1 of the first contact region CT1 and the plurality of insulating reflective structure openings 400 adjacent to the second boundary B2 of the first contact subregion CT1′ are spaced apart respectively by a first shortest distance D1 and a second shortest distance D2. The second group of insulating reflective structure openings 4002 away from the first boundary B1 of the first contact region CT1 and the plurality of insulating reflective structure openings 400 away from the second boundary B2 of the first contact subregion CT1′ are respectively evenly spaced by a first shortest pitch d1, wherein the first shortest pitch d1 is larger than the first shortest distance D1 and/or larger than the second shortest distance D2. FIG. 4 is an electrical over stress (EOS) testing diagram of the light-emitting device 1. The amount of the plurality of insulating reflective structure openings 400 per unit area is increased by reducing the distance between the plurality of insulating reflective structure openings 400, that is, the density of the plurality of insulating reflective structure openings 400 is increased. Therefore, under the same unit area, the amount of the plurality of insulating reflective structure openings 400 adjacent to the first boundary B1 of the first contact region CT1 and adjacent to the second boundary B2 of the first contact subregion CT1′ is greater than that away from the first boundary B1 of the first contact region CT1 and away from the second boundary B2 of the first contact subregion CT1′. That is, the density of the plurality of insulating reflective structure openings 400 adjacent to the first boundary B1 of the first contact region CT1 and adjacent to the second boundary B2 of the first contact subregion CT1′ is greater than that away from the first boundary B1 of the first contact region CT1 and away from the second boundary B2 of the first contact subregion CT1′, thereby improving the current injection of the light-emitting device 1 and improving the endurance of electrical over stress (EOS) of the light-emitting device 1. As shown in FIG. 4, as a comparative example of the light-emitting device, a distance between each of the plurality of insulating reflective structure openings 400 adjacent to the first contact region CT1 and adjacent to the first contact subregion CT1′ is the same as a pitch between each of the plurality of insulating reflective structure openings 400 away from the first contact region CT1 and away from the first contact subregion CT1′. Compared with the light-emitting device of the comparative example, the light-emitting device 1 comprises a first shortest distance D1 between each of the plurality of insulating reflective structure openings 400 adjacent to the first contact region CT1 and a second shortest distance D2 between each of the plurality of insulating reflective structure openings 400 adjacent to the first contact subregion CT1′ smaller than the first shortest pitch d1 between each of the plurality of insulating reflective structure openings 400 away from the first contact region CT1 and away from the first contact subregion CT1′. Under the same unit area, the light-emitting device 1 comprises greater amount of the plurality of insulating reflective structure openings 400 adjacent to the first contact region CT1 and adjacent to the first contact subregion CT1′. As shown in FIG. 4, compared with the light-emitting device of the comparative example, the light-emitting device 1 has higher endurance of EOS. The endurance of EOS and the amount of the plurality of insulating reflective structure openings 400 per unit area of the light-emitting device 1 are directly proportional. For example, compared to a comparative example with a smaller amount of the plurality of insulating reflective structure openings 400 adjacent to the first contact region CT1 and adjacent to the first contact subregion CT1′ under the same unit area, the light-emitting device 1 with higher density of the plurality of insulating reflective structure openings 400 (the amount of the plurality of insulating reflective structure openings 400 per unit area) can withstand a higher current during an electrical over stress (EOS) test, thereby avoiding breakdown of the device. The light-emitting device 1 having a design of the plurality of insulating reflective structure openings 400 of the present application can achieve good current diffusion effect. The light-emitting device 1 of the present application can reduce the light loss and provide higher electrical over stress (EOS) endurance and better electrostatic discharge (ESD) endurance.

FIG. 5A is a cross-sectional view along line O-O′ of FIG. 3A or along line P-P′ of FIG. 3B according to an embodiment of the present application. FIG. 5B is a cross-sectional view along line O-O′ of FIG. 3A or along line P-P′ of FIG. 3B according to another embodiment of the present application. A first recessed region E1 is located on at least one side of the semiconductor mesa M. The symbol “B1” represents a first boundary B1 between the first recessed region E1 and the semiconductor mesa M. The first opening 601 of the second insulating layer 60 exposes the first contact region CT1 of the first semiconductor layer 21. The plurality of insulating reflective structure openings 400 adjacent to the first boundary B1 of the first contact region CT1 comprises a first width W1 as shown in FIG. 3A or a second width W2 as shown in FIG. 3B.

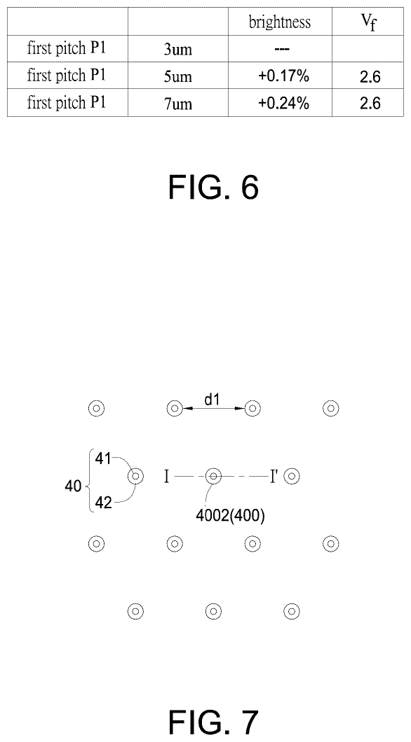

FIG. 6 compares the influence of a first pitch P1 between the first side surface S1 of the contact electrode 30 and the inclined surface S of the semiconductor mesa M on the optoelectronic characteristics of the light-emitting device 1. Taking the embodiment of FIG. 5A as an example, with the premise of the third pitch P3 between the third side surface S3 of the metal reflective layer 52 and the inclined surface S of the semiconductor mesa M set to be 6 μm, the brightness of the light-emitting device 1 tends to be increased when the first pitch P1 between the first side surface S1 of the contact electrode 30 and the inclined surface S of the semiconductor mesa M is larger. Since the reflectivity of the metal reflective layer 52 is higher than the reflectivity of the contact electrode 30, as the first pitch P1 is greater than the third pitch P3, the light at the first boundary B1 and the second boundary B2 shown in FIGS. 1 and 2 emitted from the active layer 22 do not transmit through the contact electrode 30 and thus are not partially absorbed by the contact electrode 30, and the light emits towards the first boundary B1 and the second boundary B2 can be reflected by the metal reflective layer 52 to the light-emitting surface 10t of the substrate 10 to enhance the light extraction efficiency of the light-emitting device 1, thereby improving the brightness of the light-emitting device 1.

As shown in FIG. 5B, the metal reflective layer 52 and/or the insulating reflective layer 42 covers the inclined surface S of the semiconductor mesa M. The second insulating layer 60 is located on the metal reflective layer 52 and covers the metal reflective layer 52 and the insulating reflective layer 42 on the inclined surface S of the semiconductor mesa M. The light emitted from the active layer 22 towards the inclined surface S of the semiconductor mesa M can be reflected by the metal reflective layer 52 and/or the insulating reflective layer 42 to the light-emitting surface 10t of the substrate 10 to enhance the light extraction efficiency of the light-emitting device 1, thereby improving the brightness of the light-emitting device 1. As shown in FIG. 5B, in the cross-sectional view of the light-emitting device 1, the metal reflective layer 52 covers the inclined surface S of the semiconductor mesa M and/or the insulating reflective layer 42 covers the inclined surface S of the semiconductor mesa M, so that the inclined surface S of the semiconductor mesa M is located between the first side surface S1 of the contact electrode 30 and the third side surface S3 of the metal reflective layer 52, that is, the metal reflective layer 52 and/or the insulating reflective layer 42 is located in an area outside the coverage of the contact electrode 30. In this embodiment, the metal reflective layer 52 and/or the insulating reflective layer 42 each can comprise an end portion 52t and/or 42t sandwiched between the first insulating layer 41 and the second insulating layer 60. The end portion 52t of the metal reflective layer 52 and/or the end portion 42t of the insulating reflective layer 42 comprises a wedge shape.

As shown in FIGS. 5A and 5B, the insulating reflective layer 42 of the insulating reflective structure 40 comprises a first portion 401 of the insulating reflective structure 40 located on the first semiconductor layer 21 outside the semiconductor mesa M, and a second portion 402 of the insulating reflective structure 40 covered on the inclined surface S of the semiconductor mesa M. The first portion 401 of the insulating reflective structure 40 comprises a maximum length Lₘₐₓ projected on the first semiconductor layer 21. In one embodiment, the semiconductor mesa M comprises a mesa height Hₘₑₛₐ ranging between 0.6 μm and 1.8 μm, and the maximum length Lₘₐₓ of the first portion 401 of the insulating reflective structure 40 can range between 0.2 μm and 4.8 μm, between 0.6 μm and 3.8 μm, or between 1.6 μm and 2.8 μm, and there is a ratio (Lₘₐₓ/Hₘₑₛₐ) between the maximum length Lₘₐₓ and the mesa height Hₘₑₛₐ, which can be 0.1˜2.7 or 0.7˜1.3.

The connection layer 51 is disposed on the insulating reflective structure 40. In one embodiment, the connection layer 51 contacts the contact electrode 30 through the plurality of insulating reflective structure openings 400. In another embodiment, the connection layer 51 comprising an opening (not shown) corresponding to the insulating reflective structure opening 400 is not in contact with the contact electrode 30 or is only in contact with part of the contact electrode 30, and the metal reflective layer 52 formed thereafter can be in contact with the contact electrode 30 through the opening of the connection layer 51. The contact electrode 30 and the connection layer 51 may comprise the same or different materials. Since the reflectivity of the metal reflective layer 52 is higher than the reflectivity of the connection layer 51, the connection layer 51 comprises a thickness smaller than that the contact electrode 30 comprise to avoid the light emitted from the active layer 22 to be partially absorbed by the connection layer 51 when transmitting through the connection layer 51. In one embodiment, the thickness of the contact electrode 30 is between 100 Å and 200 Å. The thickness of the connection layer 51 is between 10 Å and 90 Å. In one embodiment, the contact electrode 30 can comprise aluminum oxide, indium tin oxide (ITO), zinc doped indium tin oxide (ZITO), zinc indium oxide (ZIO), gallium indium oxide (GIO), zinc tin oxide (ZTO), fluorine doped tin oxide (FTO), aluminum doped zinc oxide (AZO), gallium doped zinc oxide (GZO), or zinc magnesium oxide (Zn₍₁₋ₓ₎MgₓO, 0≤x≤1). The connection layer 51 can comprise titanium oxide (TiOₓ), titanium nitride (TiNₓ), aluminum oxide (Al₂O₃), indium tin oxide (ITO), zinc doped indium tin oxide (ZITO), zinc indium oxide (ZIO), gallium indium oxide (GIO), zinc tin oxide (ZTO), fluorine doped tin oxide (FTO), aluminum doped zinc oxide (AZO), gallium doped zinc oxide (GZO), or zinc magnesium oxide (Zn₍₁₋ₓ₎MgₓO, 0≤x≤1).

In one embodiment, the metal reflective layer 52 fills into the plurality of insulating reflective structure openings 400 through the connecting layer 51, where the connecting layer 51 can improve the adhesion between the insulating reflective structure 40 and the metal reflective layer 52. In the cross-sectional view of the light-emitting device 1, the contact electrode 30 has a first side surface S1, the connection layer 51 has a second side surface S2, and the metal reflective layer 52 has a third side surface S3. In one embodiment, as shown in FIG. 5A, the third side surface S3 is closer to the inclined surface S of the semiconductor mesa M than the first side surface S1, that is, the third pitch P3 is smaller than the first pitch P1. The first pitch P1 between the first side surface S1 and the inclined surface S can be greater than 6 μm and less than 15 μm. The second pitch P2 is between the second side surface S2 and the inclined surface S, and the second pitch P2 can be between 0.1 μm and 6 μm. The third pitch P3 between the third side surface S3 and the inclined surface S can be between 0.1 μm and 6 μm. In one embodiment, the second side surface S2 can be closer to the inclined surface S of the semiconductor mesa M than the third side surface S3, that is, the second pitch P2 is smaller than the third pitch P3. In one embodiment, the metal reflective layer 52 can be disposed on the connection layer 51 and conform to the connection layer 51. For example, the metal reflective layer 52 may completely overlap with the connection layer 51. Specifically, the second side surface S2 may be flush with the third side surface S3 and located on the same inclined plane. In one embodiment, the third side surface S3 may be closer to the inclined surface S of the semiconductor mesa M than the second side surface S2.

In one embodiment, the metal reflective layer 52 comprises silver (Ag), chromium (Cr), nickel (Ni), titanium (Ti), aluminum (Al), rhodium (Rh), ruthenium (Ru) or the combination of materials.

In one embodiment, the light-emitting device 1 further comprises a barrier layer (not shown) disposed on the metal reflective layer 52. The barrier layer has a multi-layer structure, for example, a multi-layer structure with Ti and Ni alternately stacked.

FIG. 7 shows an enlarged view of region C defined by the dash line of FIG. 1. The plurality of insulating reflective structure openings 400 located under the second electrode pad 92 (i.e., the second group of insulating reflective structure openings 4002 shown in FIGS. 3A to 3D) is evenly spaced from each other by the first shortest pitch d1. Referring to FIGS. 3A, 3C and 7, the plurality of insulating reflective structure openings 400 surrounding the first boundary B1 of the first contact region CT1 is evenly spaced apart by a first shortest distance D1. The plurality of insulating reflective structure openings 400 adjacent to the second boundary B2 of the first contact subregion CT1′ is evenly spaced apart by a second shortest distance D2 to surround the first contact subregion CT1′. The plurality of insulating reflective structure openings 400 located inside the semiconductor mesa M is evenly spaced apart from each other by a first shortest pitch d1. In one embodiment, the first shortest pitch d1 is greater than the first shortest distance D1 and the first shortest pitch d1 is greater than the second shortest distance D2. In another embodiment, when the first shortest pitch d1 is greater than the first shortest distance D1 and the first shortest pitch d1 is greater than the second shortest distance D2, the second shortest distance D2 can be equal to, greater than or less than the first shortest distance D1. In another embodiment, the first shortest pitch d1 is greater than the first shortest distance D1, or the first shortest pitch d1 is greater than the second shortest distance D2. In one embodiment, the amount of the plurality of insulating reflective structure openings 400 surrounding the first boundary B1 of the first contact region CT1 under the same unit area (the density) is greater than the amount of the plurality of insulating reflective structure openings 400 located inside the semiconductor mesa M under the same unit area (the density), or the amount of the plurality of insulating reflective structure openings 400 adjacent to the second boundary B2 of the first contact subregion CT1′ under the same unit area (the density) is greater than the amount of the plurality of insulating reflective structure openings 400 located inside the semiconductor mesa M under the same unit area (the density).

FIG. 8 is a cross-sectional view along line I-I′ of FIG. 7 according to an embodiment of the present application. As shown in FIG. 8, in this embodiment, the insulating reflective structure 40 does not comprise the insulating reflective layer 42. The insulating reflective structure 40 comprises a first insulating layer 41, and the first insulating layer 41 is directly disposed on the contact electrode 30 on the semiconductor mesa M. The plurality of insulating reflective structure openings 400 comprises a first insulating layer second opening 412 and has a trapezoidal cross-section. As shown in FIG. 8, the first insulation layer 41 covers the contact electrode 30, and a second sidewall 412W2 of the first insulating layer second opening 412 defines the insulating reflective structure opening 400. In one embodiment, the first insulating layer second opening 412 comprises a first maximum width W1ₘₐₓ and/or comprises a first maximum height H1ₘₐₓ, wherein the first maximum width W1ₘₐₓ ranges between 1 μm and 15 μm, between 3 μm and 10 μm, or between 5 μm and 8 μm, wherein the first maximum height H1ₘₐₓ can be, for example, between 0.1 μm and 0.5 μm. The connection layer 51 covers the first insulating layer 41 and fills into the first insulating layer second opening 412 to contact the contact electrode 30. The metal reflective layer 52 is located on the connection layer 51 and fills into the first insulating layer second opening 412.

FIG. 9 is a cross-sectional view along line I-I′ of FIG. 7 according to another embodiment of the present application. As shown in FIG. 9, the insulating reflective structure opening 400 has a stepped cross-section. In this embodiment, the insulating reflective structure 40 comprises a first insulating layer 41 located on the contact electrode 30 and an insulating reflective layer 42 located on the first insulating layer 41. The first insulating layer 41 comprises one or a plurality of first insulating layer second openings 412 located on the contact electrode 30 and exposing the contact electrode 30, and the insulating reflective layer 42 comprises one or a plurality of insulating reflective layer openings 422 located on the first insulating layer 41 and exposing the contact electrode 30. The plurality of first insulating layer second openings 412 and the plurality of insulating reflective layer openings 422 can be configured one-to-one. In this embodiment, the insulating reflective structure opening 400 comprises the first insulating layer second opening 412 and the insulating reflective layer opening 422. The insulating reflective structure opening 400 is defined by a second sidewall 412W2 of the first insulating layer second opening 412 and a third sidewall 422W of the insulating reflective layer opening 422, and a second inclined angle θ2 of the second sidewall 412W2 and a third inclined angle θ3 of the third sidewall 422W can be the same or different from each other. In one embodiment, as shown in FIG. 9, the second inclined angle θ2 of the second sidewall 412W2 can be smaller than the third inclined angle θ3 of the third sidewall 422W. In one embodiment, the second inclined angle θ2 is between 10 degrees and 30 degrees, and the third inclined angle θ3 is between 40 and 70 degrees or between 30 and 60 degrees. The insulating reflective layer opening 422 comprises a second maximum width W2ₘₐₓ larger than a first maximum width W1ₘₐₓ that the first insulating layer second opening 412 comprises. The insulating reflective layer opening 422 comprises a second maximum height H2ₘₐₓ greater than or less than a first maximum height H1ₘₐₓ that the first insulating layer second opening 412 comprises. The second maximum width W2ₘₐₓ of the insulating reflective layer opening 422 can range between 6 μm and 20 μm or between 10 μm and 15 μm, and/or the second maximum height H2ₘₐₓ of the insulating reflective layer opening 422 can range between 0.1 μm and 0.5 μm. The first maximum width W1ₘₐₓ that the first insulating layer second opening 412 comprises can range between 1 μm and 15 μm, between 3 μm and 10 μm, or between 5 μm and 8 μm, and/or the first maximum height H1ₘₐₓ that the first insulating layer second opening 412 comprises can range between 0.1 μm and 0.5 μm. The connection layer 51 covers the first insulating layer 41 and the insulating reflective layer 42, and fills into the first insulating layer second opening 412 to contact the contact electrode 30. The metal reflective layer 52 is located on the connection layer 51 and fills into the first insulating layer second opening 412.

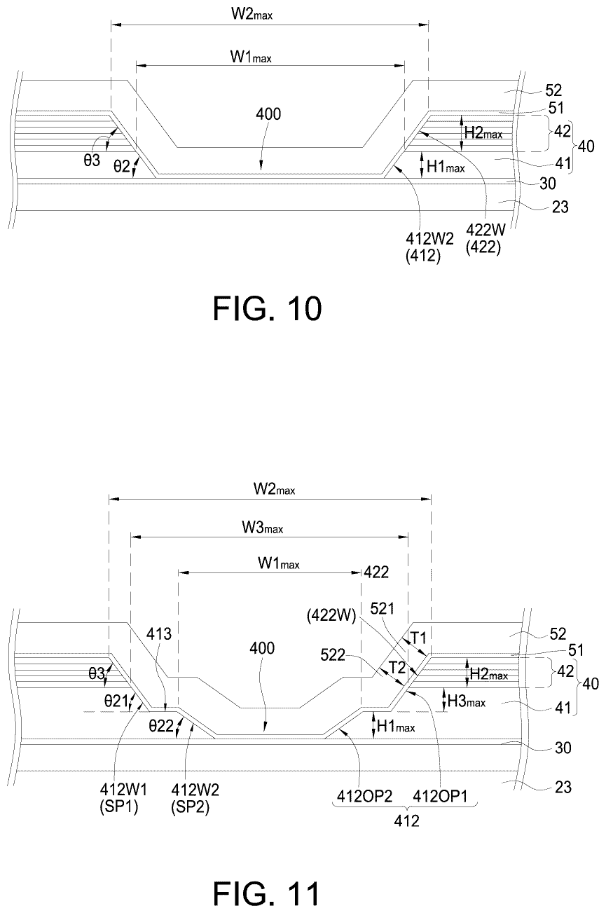

In one embodiment, as shown in FIG. 10, the insulating reflective structure opening 400 has a trapezoidal cross-section. The insulating reflective structure opening 400 is defined by a second sidewall 412W2 of the first insulating layer second opening 412 and a third sidewall 422W of the insulating reflective layer opening 422, wherein the second sidewall 412W2 of the first insulating layer second opening 412 and the third sidewall 422W of the insulating reflective layer opening 422 are directly connected. The connection layer 51 covers the insulating reflective layer 42, and fills into the insulating reflective layer opening 422 and the first insulating layer second opening 412 to contact the contact electrode 30. The metal reflective layer 52 is located on the connection layer 51 and fills into the insulating reflective layer opening 422 and the first insulating layer second opening 412. The second inclined angle θ2 of the second sidewall 412W2 and the third inclined angle θ3 of the third sidewall 422W can be the same or different from each other. In one embodiment, as shown in FIG. 10, the second inclined angle θ2 of the second sidewall 412W2 is the same as the third inclined angle θ3 of the third sidewall 422W. In one embodiment, the second inclined angle θ2 and the third inclined angle θ3 are between 40 and 70 degrees or between 30 and 60 degrees. The insulating reflective layer opening 422 comprises a second maximum width W2ₘₐₓ larger than a first maximum width W1ₘₐₓ that the first insulating layer second opening 412 comprises. The insulating reflective layer opening 422 comprises a second maximum height H2ₘₐₓ greater than or less than a first maximum height H1ₘₐₓ that the first insulating layer second opening 412 comprises. The second maximum width W2ₘₐₓ of the insulating reflective layer opening 422 can range between 6 μm and 20 μm or between 10 μm and 15 μm, and/or the second maximum height H2ₘₐₓ of the insulating reflective layer opening 422 can range between 0.1 μm and 0.5 μm. The first maximum width W1ₘₐₓ that the first insulating layer second opening 412 comprises can range between 1 μm and 15 μm, between 3 μm and 10 μm, or between 5 μm and 8 μm, and/or the first maximum height H1ₘₐₓ that the first insulating layer second opening 412 comprises can range between 0.1 μm and 0.5 μm. The connection layer 51 covers the first insulating layer 41 and the insulating reflective layer 42, and fills into the first insulating layer second opening 412 to contact the contact electrode 30. The metal reflective layer 52 is located on the connection layer 51 and fills into the first insulating layer second opening 412.

In one embodiment, as shown in FIG. 11, the insulating reflective structure opening 400 has a stepped cross-section. The first insulating layer second opening 412 comprises a first insulating layer second upper opening 412OP1 and a first insulating layer second lower opening 412OP2. The first insulating layer second upper opening 412OP1 comprises a first sidewall 412W1, and the first sidewall 412W1 can be a first inclined surface SP1 comprising a first slope. The first insulating layer second lower opening 412OP2 comprises a second sidewall 412W2, and the second sidewall 412W2 can be a second inclined surface SP2 comprising a second slope. The first slope of the first inclined surface SP1 can be different from the second slope of the second inclined surface SP2. The first insulating layer 41 further comprises a first insulating layer upper surface 413, the first insulating layer upper surface 413 comprises two ends connected to the first inclined surface SP1 and the second inclined surface SP2 respectively. In this embodiment, the insulating reflective structure opening 400 is defined by the first sidewall 412W1 (the first inclined surface SP1) of the first insulating layer second upper opening 412OP1, the second sidewall 412W2 (the second inclined surface SP2) of the first insulating layer second lower opening 412OP2, and the third sidewall 422W of the insulating reflective layer opening 422. The first inclined surface SP1 comprises an inclined angle θ21, and the second inclined surface SP2 comprises an inclined angle θ22. The inclined angle θ21 and the inclined angle θ22 can be the same as or different from each other. In one embodiment, as shown in FIG. 11, the inclined angle θ22 of the second inclined surface SP2 can be smaller than the inclined angle θ21 of the first inclined surface SP1 or the third inclined angle θ3 of the third sidewall 422W. The inclined angle θ22 of the second inclined surface SP2 can be the same as, smaller than, or greater than the third inclined angle θ3 of the third sidewall 422W. In one embodiment, the inclined angle θ22 is between 10 degrees and 30 degrees, and the third inclined angle θ3 and the inclined angle θ21 are between 40 and 70 degrees or between 30 and 60 degrees. The insulating reflective layer opening 422 comprises a second maximum width W2ₘₐₓ, the first insulating layer second lower opening 412OP2 comprises a first maximum width W1ₘₐₓ, and the first insulating layer second upper opening 412OP1 comprises a third maximum width W3ₘₐₓ. In one embodiment, the second maximum width W2ₘₐₓ of the insulating reflective layer opening 422 Is larger than the first maximum width W1ₘₐₓ of the first insulating layer second lower opening 412OP2, and is larger than the third maximum width W3ₘₐₓ of the first insulating layer second upper opening 412OP1, wherein the third maximum width W3ₘₐₓ is larger than the first maximum width W1ₘₐₓ. In one embodiment, the insulating reflective layer opening 422 comprises a second maximum height H2ₘₐₓ, the first insulating layer second lower opening 412OP2 comprises a first maximum height H1ₘₐₓ, and the first insulating layer second upper opening 412OP1 comprises a third maximum height H3ₘₐₓ. In one embodiment, the third maximum height H3ₘₐₓ can be larger than the first maximum height H1ₘₐₓ, and/or larger than the second maximum height H2ₘₐₓ. The third maximum height H3ₘₐₓ of the first insulating layer second upper opening 412OP1 can range between 0.05 μm and 0.5 μm or between 0.1 μm and 0.3 μm. The second maximum width W2ₘₐₓ of the insulating reflective layer opening 422 can range between 6 μm and 20 μm or between 10 μm and 15 μm, and/or the second maximum height H2ₘₐₓ of the insulating reflective layer opening 422 can range between 0.1 μm and 0.5 μm. The first maximum width W1ₘₐₓ of the first insulating layer second lower opening 412OP2 can range between 1 μm and 15 μm, between 3 μm and 10 μm, or between 5 μm and 8 μm, and/or the first maximum height H1ₘₐₓ of the first insulating layer second lower opening 412OP2 can range between 0.1 μm and 0.5 μm. The connection layer 51 covers the first insulating layer 41 and the insulating reflective layer 42, and fills into the first insulating layer second opening 412 to contact the contact electrode 30. The metal reflective layer 52 is located on the connection layer 51 and fills into the first insulating layer second opening 412.

In this embodiment (not shown), the insulating reflective structure opening 400 is defined by the second sidewall 412W2 of first insulating layer second opening 412, and the third sidewall 422W of the insulating reflective layer opening 422. The contact electrode 30 can comprise a recessed region (not shown) and have a sidewall (not shown) corresponding to the first insulating layer second opening 412. The second sidewall 412W2 can extend to the contact electrode 30 and be connected with the sidewall in the recessed region of the contact electrode 30. In one embodiment, the recessed region of the contact electrode 30 can be formed by removing a part of the contact electrode 30 when forming the first insulating layer second opening 412. For example, when a part of the first insulating layer 41 is removed by etching to form the first insulating layer second opening 412, a part of the contact electrode 30 is also removed due to over-etching to further form a recessed region.

In this embodiment (not shown), the insulating reflective structure 40 does not comprise the first insulating layer 41, and the insulating reflective layer 42 is directly disposed on the contact electrode 30 on the semiconductor mesa M. The insulating reflective structure opening 400 is defined by the third sidewall 422W of the insulating reflective layer opening 422. The contact electrode 30 can comprise a recessed region (not shown) and have a sidewall (not shown) corresponding to the insulating reflective layer opening 422. The third sidewall 422W can extend to the contact electrode 30 and be connected with the sidewall in the recessed region of the contact electrode 30. In one embodiment, the recessed region of the contact electrode 30 can be formed by removing a part of the contact electrode 30 when forming the insulating reflective layer opening 422. For example, when a part of the insulating reflective layer 42 is removed by etching to form the insulating reflective layer opening 422, a part of the contact electrode 30 is also removed due to over-etching to further form a recessed region.

In this embodiment (not shown), the light-emitting device 1 further comprises a dielectric layer covering the third sidewall 422W of the insulating reflective layer opening 422 and connected to the first insulating layer upper surface 413. The dielectric layer can be made of a transparent insulating material and comprises one of the following materials: SiO₂, SiN, TiO₂, HfO, Al₂O₃, and MgF₂. As shown in FIG. 11, the metal reflective layer 52 comprises a first portion 521 covering the third sidewall 422W of the insulating reflective layer opening 422, and a second portion 522 covering the first sidewall 412W1 of the first insulating layer second upper opening 412OP1 or the second sidewall 412W2 of the first insulating layer second lower opening 412OP2, wherein the second portion 522 comprises a second thickness T2 which is larger than, less than or equal to 50% of a first thickness T1 that the first portion 521 comprises.

As shown in FIG. 2, the second insulating layer 60 covers all exposed surfaces continuously of the metal reflective layer 52 and the connection layer 51 to protect the metal reflective layer 52, such as the upper surfaces and side surfaces of the metal reflective layer 52 and those of the connection layer 51 (including the second side surface S2 and the third side surface S3). The metal reflective layer 52 and the connection layer 51 may be sandwiched and/or encapsulated between the second insulating layer 60 and the insulating reflective structure 40. Forming the second insulating layer 60 can prevent the reflectivity of the metal reflective layer 52 from degradation caused by subsequent processes and suppress the migration of metal elements that the metal reflective layer 52 comprises. The second insulating layer 60 may be made of a transparent insulating material comprising SiO₂, SiN, TiO₂, HfO, or MgF₂.

The insulating reflective structure 40, the connection layer 51 and the metal reflective layer 52 may be configured as an Omni-Directional reflector (ODR). The Omni-Directional reflector can increase the reflectivity of light emitted from the active layer 22, thereby improving the light extraction efficiency of the light-emitting device 1.

When the second insulating layer 60 is made of a transparent insulating material, the second insulating layer 60 comprises a first opening 601 and a second opening 602 of the second insulating layer 60. The first opening 601 of the second insulating layer 60 can pass through the insulating reflective structure 40 to expose the first semiconductor layer 21 in the first contact region CT1 and the first contact subregion CT1′. The first opening 601 of the second insulating layer 60 can be disposed on the first recessed region E1 and the second recessed region E2. The second opening 602 of the second insulating layer 60 can be located on the metal reflective layer 52 in the second contact region CT2.

In one embodiment, as shown in FIG. 1, in order to make the plurality of insulating reflective structure openings 400 arranged evenly spaced, the second opening 602 of the second insulating layer 60 comprises an irregular rounded shape, and the plurality of insulating reflective structure openings 400 are surrounded by the irregular rounded shape, wherein the second opening 602 of the second insulating layer 60 does not overlap with the plurality of insulating reflective structure openings 400. In one embodiment, the second opening 602 of the second insulating layer 60 comprises a closed curved outer contour, and the plurality of insulating reflective structure openings 400 comprises a first portion located inside the closed curved outer contour and a second portion located outside the closed curved outer contour, wherein the first portion and the second portion are arranged on the semiconductor mesa M in a hexagonal grid pattern.

The first extension electrode 71 can be disposed on the second insulating layer 60 and extend to the first semiconductor layer 21 in the first contact region CT1 and the first contact subregion CT1′ to contact and be electrically connected to the first semiconductor layer 21 through the first opening 601 of the second insulating layer 60. In one embodiment, in order to improve the contact resistance characteristics between the first extension electrode 71 and the first semiconductor layer 21, a conductive contact layer (not shown) can be disposed between the first extension electrode 71 and the first semiconductor layer 21. The conductive contact layer can comprise indium tin oxide (ITO), zinc doped indium tin oxide (ZITO), zinc indium oxide (ZIO), gallium indium oxide (GIO), zinc tin oxide (ZTO), fluorine doped tin oxide (FTO), aluminum-doped zinc oxide (AZO), gallium-doped zinc oxide (GZO), zinc-magnesium oxide (Zn₍₁₋ₓ₎MgₓO, 0≤x≤1) and other conductive metal oxides. In one embodiment, a metal contact layer (not shown) can be disposed on the upper surface 20b of the first recessed region E1 and/or the upper surface 20b′ of the second recessed region E2. A part of the upper surface of the metal contact layer can be the first contact region CT1 and/or the first contact subregion CT1′

The second extension electrode 72 can be disposed on the second insulating layer 60 and extend to contact the metal reflective layer 52 through the second opening 602 of the second insulating layer 60, thereby being electrically connected to the second semiconductor layer 23.

The first extension electrode 71 and the second extension electrode 72 can be disposed on the second insulating layer 60, made of the same material, and spaced apart from each other. For example, the first extension electrode 71 and the second extension electrode 72 may be made of a material comprising aluminum (Al), gold (Au), tungsten (W), platinum (Pt), iridium (Ir), silver (Ag), copper (Cu), nickel (Ni), titanium (Ti), chromium (Cr) and alloys of the above materials. As shown in FIG. 1, in a top view, the second extension electrode 72 can be surrounded by the first extension electrode 71 completely, or can be partially surrounded by the first extension electrode 71 (not shown).

The protection layer 80 comprises a first opening 801 of the protection layer 80 located on the first extension electrode 71 and a second opening 802 of the protection layer 80 located on the second extension electrode 72. The first opening 801 of the protection layer 80 can expose the third contact region CT3 of the first extension electrode 71, and the second opening 802 of the protection layer 80 can expose the fourth contact region CT4 of the second extension electrode 72.

The first electrode pad 91 can be disposed on the third contact region CT3 of the first extension electrode 71, and the second electrode pad 92 can be disposed on the fourth contact region CT4 of the second extension electrode 72. The first electrode pad 91 can be adjacent to the first side 11, and the second electrode pad 92 can be adjacent to the second side 12. A first soldering pad (not shown) can be disposed on the first electrode pad 91, and a second soldering pad (not shown) can be disposed on the second electrode pad 92. The first soldering pad and the second soldering pad can be made of a conductive material (e.g., Sn or AuSn).

The first extension electrode 71, the second extension electrode 72, the first electrode pad 91, and the second electrode pad 92 comprise metal materials, such as chromium (Cr), titanium (Ti), tungsten (W), gold (Au), aluminum (Al), indium (In), tin (Sn), nickel (Ni), platinum (Pt), silver (Ag) and other metals or alloys of the above materials. The first extension electrode 71, the second extension electrode 72, the first electrode pad 91, and the second electrode pad 92 can be composed of a single layer or multiple layers. For example, the first extension electrode 71, the second extension electrode 72, the first electrode pad 91, or the second electrode pad 92 can comprise a Ti/Au layer, a Ti/Pt/Au layer, a Cr/Au layer, a Cr/Pt/Au layer, a Ni/Au layer, a Ni/Pt/Au layer, a Cr/Al/Cr/Ni/Au layer, or a Ag/NiTi/TiW/Pt layer. The first electrode pad 91 and the second electrode pad 92 can serve as current paths for external power supply into the first semiconductor layer 21 and the second semiconductor layer 23. The first extension electrode 71, the second extension electrode 72, the first electrode pad 91, and the second electrode pad 92 each comprises a thickness in a range between 0.5 μm and 5 μm.

The first insulating layer 41, the second insulating layer 60 and the protection layer 80 are disposed on the semiconductor structure 20 and serve as a protection film and an anti-static interlayer insulating film for the light-emitting device 1. In one embodiment, as an insulating film, the first insulating layer 41, the second insulating layer 60 and the protection layer 80 can be a single-layer structure, comprising silicon oxide, silicon nitride, metal oxide or metal nitride. For example, the metal of metal oxide or metal nitride can be selected from titanium (Ti), zirconium (Zr), niobium (Nb), tantalum (Ta), or aluminum (Al). In one embodiment, the first insulating layer 41, the second insulating layer 60 and the protection layer 80 comprise two or more materials with different refractive indexes that are alternately stacked to form a distributed Bragg reflector (DBR) structure to selectively reflect light of specific wavelengths. For example, an insulating reflective structure with high reflectivity can be formed by stacking SiO₂/TiO₂ or SiO₂/Nb₂O₅ sub-layers. When SiO₂/TiO₂ or SiO₂/Nb₂O₅ sub-layers are stacked to form a distributed Bragg reflector (DBR) structure, an optical thickness of each sub-layer of the distributed Bragg reflector structure is designed to be one or an integer multiple of a quarter of the wavelength of the light emitted from the active layer 22. The optical thickness of each sub-layer of the distributed Bragg reflector structure may have a deviation of ±30% based on one or an integer multiple of λ/4. Since the change in the optical thickness of each sub-layer of the distributed Bragg reflector structure can affect the reflectivity, the physical thickness of each sub-layer of the first insulating layer 41, the second insulating layer 60 and the protection layer 80 which is obtained based on the optical thickness of the distributed Bragg reflector structure can be formed by using E-beam evaporation to stably control the thickness of each sub-layer of the first insulating layer 41, the second insulating layer 60 and the protection layer 80.

In one embodiment of the present application, when the insulating reflective layer 42 comprises a distributed Bragg reflector structure with stacked SiO₂/TiO₂ or SiO₂/Nb₂O₅, the first insulating layer 41 has a thickness greater than a thickness of each sub-layer that the insulating reflective layer 42 comprises. In one embodiment of the present application, the thickness of the first insulating layer 41 ranges between 3000 Å and 7000 Å.

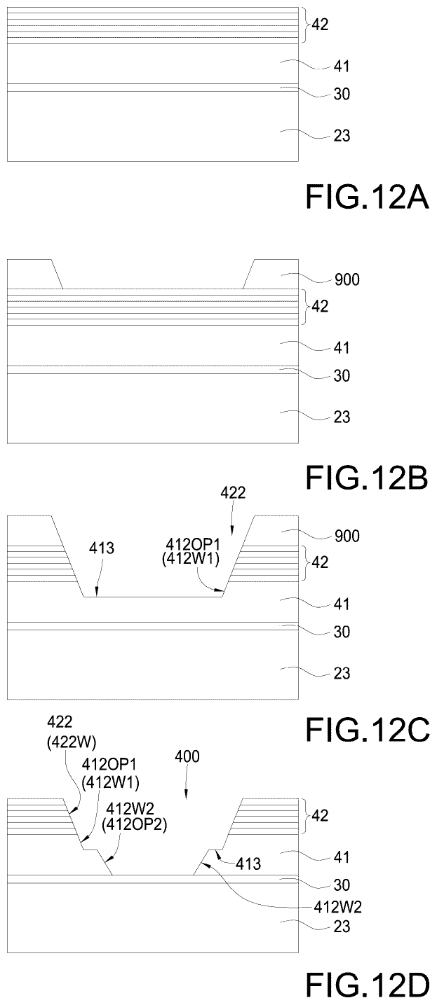

FIGS. 12A to 12D are cross-sectional views of a method for manufacturing the insulating reflective structure opening 400 of the light-emitting device 1 disclosed in an embodiment of the present application.

As shown in FIG. 12A, a contact electrode 30 that can form ohmic contact with the second semiconductor layer 23 is first formed. Then, a first insulating layer 41 is formed on the contact electrode 30, and an insulating reflective layer 42 is formed on the first insulating layer 41. Referring to FIGS. 5A and 5B, when the insulating reflective layer 42 covers the inclined surface S of the semiconductor mesa M, the angle of the inclined surface S can affect the coating quality of the insulating reflective layer 42. For example, when the insulating reflective layer 42 covers the semiconductor mesa M, it tends to form a fracture surface (not shown) at the junction between the inclined surface S of the semiconductor mesa M and the upper surface 21t of the first semiconductor layer 21 or at the junction between the inclined surface S of the semiconductor mesa M and the upper surface 23t of the second semiconductor layer 23. Thus, water vapor form outside tends to invade the semiconductor structure 20 through the fracture surface to reduce the reliability of the light-emitting device 1. In order to solve the problem caused from the above-mentioned fracture, in this embodiment, the first insulating layer 41 is formed before forming the insulating reflective layer 42. The first insulating layer 41 has a denser film quality than the insulating reflective layer 42 and/or has a more uniform film thickness. When the insulating reflective layer 42 comprises a plurality of sub-layers, the film thickness of the first insulating layer 41 is thicker than the thickness of the plurality of sub-layers of the insulating reflective layer 42. The first insulating layer 41 can be formed by the same or different method for manufacturing the insulating reflective layer 42. In one embodiment, chemical vapor deposition (CVD) or plasma enhanced chemical vapor deposition (PECVD) may be used to form the first insulating layer 41 with better coverage and coating characteristics. In one embodiment, the high step coverage characteristics of atomic layer deposition (ALD) can be utilized to form the insulating reflective layer 42 or the first insulating layer 41 with uniform thickness. When the insulating reflective layer 42 comprises a distributed Bragg reflector (DBR) structure, the thickness of each sub-layer of the distributed Bragg reflector (DBR) structure can affect the reflectivity of the insulating reflective layer 42. In this embodiment, the insulating reflective layer 42 can be formed by E-beam evaporation to stably control the thickness of each sub-layer of the distributed Bragg reflector (DBR) structure.

As shown in FIG. 12B, a mask layer 900 is formed on the insulating reflective layer 42 by steps including spin coating, exposure, and development. As shown in FIG. 12C, part of the insulating reflective layer 42 where not covered by the mask layer 900 is removed by a first etching, wherein the method of removing the insulating reflective layer 42 comprises dry etching or wet etching. In one embodiment, it can be performed to use the mask layer 900 having openings of a first diameter to dry etch the insulating reflective layer 42 to form a plurality of insulating reflective layer openings 422. The first insulating layer 41 can serve as a protection layer or a stop layer for dry etching to prevent the contact electrode 30 and the second semiconductor layer 23 of the light-emitting device 1 from damage caused by the plasma ion source during the dry etching process. To prevent the residue of the insulating reflective layer 42, the first insulating layer 41 may be over-etched by 5% to 30% during the first etching to form the first insulating layer second upper opening 412OP1 and expose the first insulating layer upper surface 413 to ensure that there is no residue of the insulating reflective layer 42. During the process of forming the insulating reflective layer opening 422 and the first insulating layer second upper opening 412OP1, the third sidewall 422W of the insulating reflective layer opening 422 and the first sidewall 412W1 of the first insulating layer second upper opening 412OP1 can be formed with the same or different slopes.

As shown in FIG. 12D, the first insulating layer 41 is removed by a second etching until the contact electrode 30 is exposed. In one embodiment, it can be performed by using a mask layer (not shown) having openings of a second diameter to remove the first insulating layer 41 to form a first insulating layer second lower opening 412OP2. The method of removing the first insulating layer 41 in the second etching may be the same as or different from the method of removing the insulating reflective layer 42 in the first etching. In this embodiment, the first etching is performed by dry etching, and the second etching is performed by wet etching which is different from the first etching. In one embodiment, the second diameter of the mask layer during the second etching process can be less than the first diameter of the mask layer during the first etching process. The mask layer 900 comprises a material that is easily removable, such as polyimide or photoresist. When the material of the mask layer 900 is polyimide or photoresist, it can be removed by plasma etching. In one embodiment, the second etching can be performed by adjusting the etching gas or liquid to reduce the damage to the contact electrode 30 during the second etching to meet the requirement of less physical damage. In another embodiment, the damage to the contact electrode 30 caused by the second etching can be reduced by reducing the etching time.

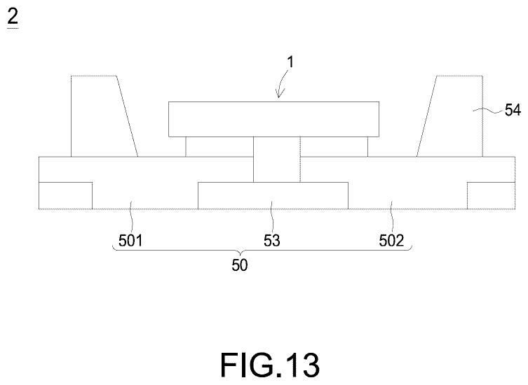

FIG. 13 is a schematic view of a light-emitting apparatus 2 disclosed in an embodiment of the present application. The light-emitting device 1 can be selected from the foregoing embodiments, and is mounted on the first spacer 501 and the second spacer 502 of the package substrate 50 in the form of flip-chip. The first spacer 501 and the second spacer 502 are electrically insulated from each other by an insulating portion 53 comprising an insulating material. The main light-extraction surface of the flip-chip is one side of the growth substrates opposite to the surface where the electrode pad formed thereon. For example, the light-emitting surface 10t of the substrate 10 of the light-emitting device 1 is the main light-extraction surface. A reflective structure 54 can be provided around the light-emitting device 1 to increase the light extraction efficiency of the light-emitting apparatus 2.

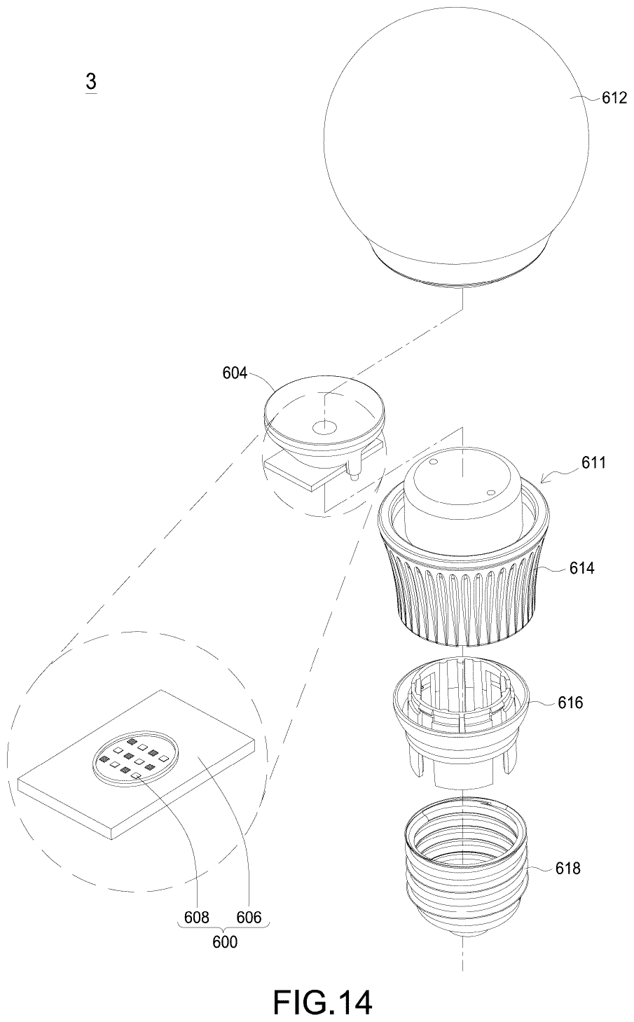

FIG. 14 is a schematic view of a light-emitting apparatus 3 disclosed in an embodiment of the present application. The light-emitting apparatus 3 is a light bulb comprising an envelope 612, a lens 604, a light-emitting module 600, a base 611, a heat sink 614, a connector 616 and an electrical connecting device 618. The light-emitting module 600 comprises a submount 606 and a plurality of light-emitting devices 608 on the submount 606, wherein the plurality of light-emitting devices 608 can be the light-emitting device 1 or the light-emitting apparatus 2 described in above embodiments.

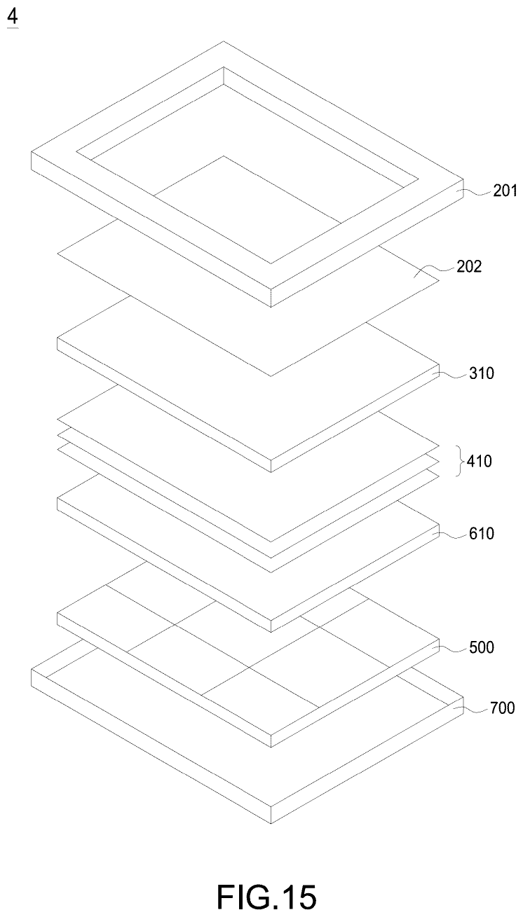

FIG. 15 is a schematic view of the backlight module 4 according to an embodiment of the present application. The backlight module 4 comprises a first frame 201, a liquid crystal display panel 202, a brightness enhancement film 310, an optical module 410, a light-emitting module assembly 500, and a second frame 700. The light-emitting module assembly 500 comprises a plurality of the light-emitting devices 1 or the light-emitting apparatuses 2 described in above embodiments, which are arranged in the light-emitting module assembly 500 in an edge type or direct type light emission manner. In one embodiment, the backlight module 4 further comprises a wavelength conversion structure 610 disposed on the light-emitting module assembly 500.

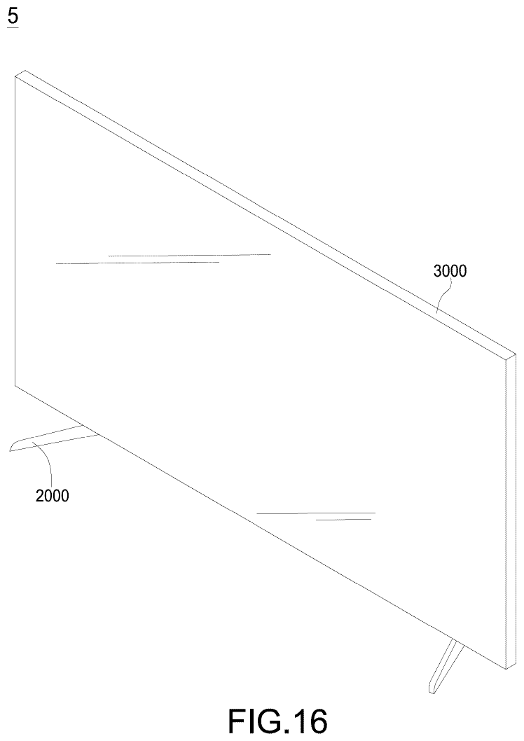

FIG. 16 is a schematic view of a display 5 according to an embodiment of the present application. The display 5 comprises an LED light-emitting panel 3000 and a current source (not shown). The bracket 2000 is used to support the LED light-emitting panel 3000. The LED light-emitting panel 3000 comprises the plurality of the light-emitting devices 1 or any one of the light-emitting apparatuses 2 or the backlight module 4 described in above embodiments. In one embodiment, the LED light-emitting panel 3000 comprises a plurality of pixel units. Each pixel unit comprises a plurality of the light-emitting devices 1 or light-emitting apparatuses 2 in the aforementioned embodiments to respectively emit different colors. For example, each pixel unit comprises three light-emitting devices 1 or light-emitting apparatuses 2 that respectively emit red light, green light, and blue light.

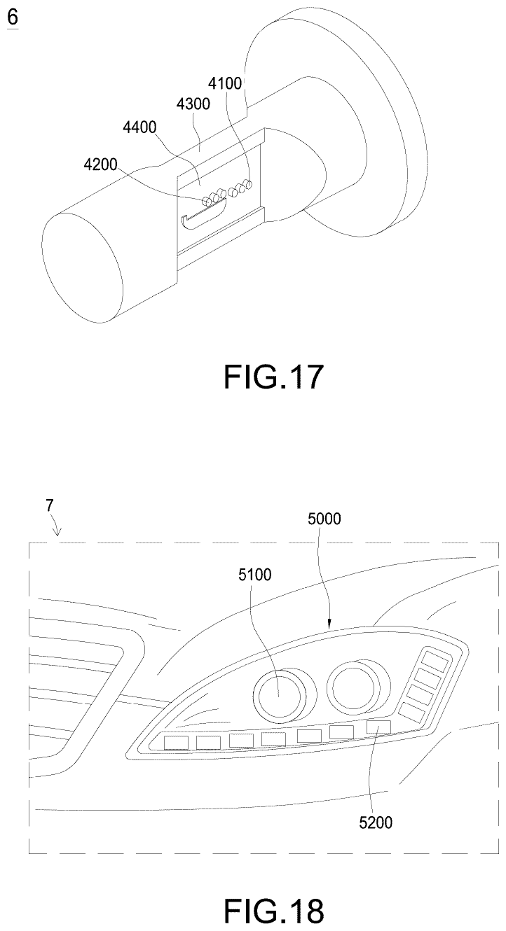

FIG. 17 is a schematic view of a light emitting apparatus 6 according to an embodiment of the present application. In one embodiment, the light-emitting apparatus 6 is an LED bulb for automobiles, which can be plugged and fixed into the mounting through hole on the rear housing of the automobile headlight assembly. The light-emitting apparatus 6 comprises a first LED chip 4100 for low beam lighting or a second LED chip 4200 for high beam lighting, a long columnar lamp post 4300, a driving power circuit board 4400, and heat dissipation fins for heat dissipation (not shown), a fan for heat dissipation (not shown), a fan cover for protecting the fan (not shown), a power cord for electrical connection with the vehicle battery (not shown), and a plug arranged at the end of the power cord (not shown). The first LED chip 4100 or the second LED chip 4200 in the light-emitting apparatus 6 may comprise any one or more of the aforementioned light-emitting devices 1 or light-emitting apparatuses 2.

FIG. 18 is a schematic view of a light emitting apparatus 7 according to an embodiment of the present application. In one embodiment, the light-emitting apparatus 7 can be a vehicle lighting lamp 5000, which can be applied in daytime running lights, headlights, tail lights, or direction lights. The main lighting lamp 5100 may be a main light-emitting lamp in the vehicle lighting lamp 5000. For example, when the vehicle lighting lamp 5000 is taken as a headlight, the main lighting lamp 5100 may function as a headlight that can illuminate the front of the vehicle. The combination lighting lamp 5200 can have at least two functions. For example, when the vehicle lighting lamp is used as a headlight, the combination lighting lamp 5200 can perform the functions of a daytime running light (DRL) and a direction indicator lamp. The main lighting lamp 5100 or the combination lighting lamp 5200 may comprise any one or more of the aforementioned light-emitting devices 1 or light-emitting apparatuses 2.

The elements of some of the embodiments as described above can facilitate those with ordinary knowledge in the technical field to which this disclosure belongs to better understand the viewpoints of the embodiments of the present disclosure. Those with ordinary skill in the art to which this disclosure belongs should understand that they can design or modify other processes and structures based on the embodiments of the disclosure to achieve the same purposes and/or advantages as the embodiments introduced here. Those with ordinary knowledge in the technical field to which this disclosure belongs should also understand that such equivalent structures do not deviate from the spirit and scope of the disclosure, and they can do various changes, replacements and substitutions without departing from the spirit and scope of this disclosure. Therefore, the protection scope of the present disclosure shall be subject to the scope of the appended claims. In addition, although the disclosure has been disclosed with several preferred embodiments as above, they are not intended to limit the disclosure.

Reference throughout the specification to features, advantages, or similar language does not imply that all features and advantages that can be realized with the present disclosure should or can be realized in any single embodiment of the present disclosure. In contrast, language referring to features and advantages is to be understood to mean that a particular feature, advantage, or characteristic described in connection with the embodiment is of at least an embodiment of the present disclosure. Thus, discussions of features and advantages, and similar language, throughout the specification may, but not necessarily, be representative of the same embodiments.

Furthermore, the described features, advantages, and characteristics of the present disclosure may be combined in any suitable manner in one or more embodiments. From the description herein, those skilled in the relevant art will appreciate that the present disclosure may be practiced without one or more of the specific features or advantages of a particular embodiment. In other instances, additional features and advantages may be identified in certain embodiments that may not be present in all embodiments of the present disclosure.

What is claimed is:

1. A light-emitting device, comprising:
a first semiconductor layer;
a semiconductor mesa, comprising an active layer and a second semiconductor layer and comprising an inclined surface connected to the first semiconductor layer;
a contact electrode covering the second semiconductor layer and comprising a first side surface;
an insulating reflective structure covering the contact electrode and comprising a plurality of insulating reflective structure openings to expose the contact electrode;
a connection layer covering the insulating reflective structure and filling into the plurality of insulating reflective structure openings, and comprising a second side surface; and
a metal reflective layer covering the connection layer and filling into the plurality of insulating reflective structure openings of the insulating reflective structure, and comprising a third side surface;
wherein in a cross-sectional view of the light-emitting device,
a first pitch is between the first side surface and the inclined surface, a third pitch is between the third side surface and the inclined surface, and the third pitch is smaller than the first pitch.

2. The light-emitting device according to claim 1, wherein the first pitch is greater than 6 μm.

3. The light-emitting device according to claim 1, wherein a second pitch is between the second side surface and the inclined surface and is in a range between 0.1 μm and 6 μm.

4. The light-emitting device according to claim 1, wherein the third pitch is in a range between 0.1 μm and 6 μm.

5. The light-emitting device according to claim 1, wherein a second pitch is between the second side surface and the inclined surface, and the second pitch is smaller than the third pitch.

6. The light-emitting device according to claim 1, wherein the second side surface is flush with the third side surface in the cross-sectional view of the light-emitting device.

7. The light-emitting device according to claim 1, wherein the contact electrode and the connection layer comprise the same materials.

8. The light-emitting device according to claim 1, wherein the contact electrode and the connection layer comprise different materials.

9. The light-emitting device according to claim 1, wherein a thickness of the connection layer is smaller than a thickness of the contact electrode.

10. The light-emitting device according to claim 1, wherein the insulating reflective structure comprises a distributed Bragg reflector (DBR) covering the inclined surface of the semiconductor mesa, and covering the first semiconductor layer.

11. The light-emitting device according to claim 1, wherein in the cross-sectional view of the light-emitting device, the metal reflective layer covers the inclined surface of the semiconductor mesa, and the inclined surface of the semiconductor mesa is between the first side surface of the contact electrode and the third side surface of the metal reflective layer.

12. The light-emitting device according to claim 1, further comprises a second insulating layer covering the metal reflective layer and the insulating reflective structure, wherein the insulating reflective structure comprises a first insulating layer and an insulating reflective layer covering the inclined surface of the semiconductor mesa, and the insulating reflective layer comprises an end disposed between the first insulating layer and the second insulating layer.

13. The light-emitting device according to claim 12, wherein the first insulating layer comprises a plurality of first insulating layer openings to expose the contact electrode, and the insulating reflective layer comprises a plurality of insulating reflective layer openings located on the first insulating layer, and the plurality of insulating reflective layer openings each is correspondingly disposed on the plurality of first insulating layer openings.

14. The light-emitting device according to claim 13, wherein one of the plurality of first insulating layer openings comprises a second sidewall, and one of the plurality of insulating reflective layer openings disposed on the one of the plurality of first insulating layer openings comprises a third sidewall, and wherein a second inclined angle of the second sidewall is the same as a third inclined angle of the third sidewall.

15. The light-emitting device according to claim 14, wherein the connection layer covers the third sidewall of the plurality of insulating reflective layer openings and second sidewall of the plurality of first insulating layer openings and directly contacts the contact electrode.

16. The light-emitting device according to claim 12, wherein the first insulating layer comprises a plurality of first insulating layer openings to expose the contact electrode, each of the plurality of first insulating layer openings comprises a first insulating layer upper opening and a first insulating layer lower opening, and wherein the first insulating layer upper opening comprises a first inclined surface having a first slope, the first insulating layer lower opening comprises a second inclined surface having a second slope, and the first slope is different from the second slope.

17. The light-emitting device according to claim 16, wherein the first insulating layer further comprises a first insulating layer upper surface, and the first insulating layer upper surface comprises two ends connected to the first inclined surface and the second inclined surface respectively.

18. The light-emitting device according to claim 16, wherein one of the plurality of insulating reflective layer openings comprises an inclined surface having a slope different from the first slope of the first inclined surface of the first insulating layer upper opening that one of the plurality of first insulating layer openings comprises.

19. The light-emitting device according to claim 18, wherein the metal reflective layer comprises a first portion covering the inclined surface of the one of the plurality of insulating reflective layer openings and a second portion covering the first inclined surface of the first insulating layer upper opening or the second inclined surface of the first insulating layer lower opening that the one of the plurality of first insulating layer openings comprises, wherein the second portion comprises a second thickness which is lower than or equal to 50% of a first thickness that the first portion comprises.

20. The light-emitting device according to claim 18, wherein the metal reflective layer comprises a first portion covering the inclined surface of the one of the plurality of insulating reflective layer openings and a second portion covering the first inclined surface of the first insulating layer upper opening or in the second inclined surface of the first insulating layer lower opening that the one of the plurality of first insulating layer openings comprises, wherein the second portion comprises a second thickness which is larger than or equal to 50% of a first thickness that the first portion comprises.
